(19) United States
(12) Patent Application Publication
(10) Pub. No.: US 2025/0374419 A1
(43) Pub. Date: Dec. 4, 2025

(54) PRINTED CIRCUIT BOARD

(71) Applicant: SAMSUNG ELECTRO-MECHANICS CO., LTD., Suwon-si (KR)

(72) Inventor: Sang Hyuk Son, Suwon-si (KR)

(73) Assignee: SAMSUNG ELECTRO-MECHANICS CO., LTD., Suwon-si (KR)

(21) Appl. No.: 19/061,595

(22) Filed: Feb. 24, 2025

(30) Foreign Application Priority Data
Jun. 4, 2024 (KR) 10-2024-0073127

(51) Int. Cl. H05K 1/02; H05K 1/11; H05K 1/18

(52) U.S. Cl. CPC H05K 1/0271; H05K 1/112; H05K 1/185; H05K 2201/09136; H05K 2201/2009

(57) ABSTRACT

The present disclosure relates to a printed circuit board, the printed circuit board including: a reinforcing layer; a first insulating layer disposed above the reinforcing layer; a second insulating layer disposed below the reinforcing layer; a first cavity penetrating at least a portion of the first insulating layer; a second cavity penetrating at least a portion of the second insulating layer; a first electronic component disposed within the first cavity; and a second electronic component disposed within the second cavity. The reinforcing layer has a higher degree of stiffness than that of the first insulating layer, and the first insulating layer and the second insulating layer have substantially different thicknesses.

### CROSS-REFERENCE TO RELATED APPLICATIONS

This application claims benefit of priority to Korean Patent Application No. 10-2024-0073127 filed on Jun. 4, 2024 in the Korean Intellectual Property Office, the disclosure of which is incorporated herein by reference in its entirety.

### BACKGROUND

### 1. Field

The present disclosure relates to a printed circuit board.

### 2. Description of Related Art

A multi-chip package including a memory chip such as high bandwidth memory (HBM), a processor chip such as a central processing unit (CPU), a graphics processing unit (GPU), an application specific integrated circuit (ASIC), a field programmable gate array (FPGA), and the like, is being used for data processing that has increased exponentially due to the recent development of artificial intelligence (AI) technology, or the like. In particular, the number of CPU and GPU cores in server products has increased rapidly, and the size of the substrate is increasing due to increased area and multilayer structures. Accordingly, research is being conducted to control bending characteristics while mounting various electronic components.

### SUMMARY

An aspect of the present disclosure is to provide a printed circuit board for controlling warpage on a multilayer substrate while implementing a cavity for mounting electronic components, or the like.

Another aspect of the present disclosure is to provide a printed circuit board for mounting various types of electronic components.

Another aspect of the present disclosure is to provide a printed circuit board for improving reliability.

According to an aspect of the present disclosure, provided is a printed circuit board, the printed circuit board including: a reinforcing layer; a first insulating layer disposed above the reinforcing layer; a second insulating layer disposed below the reinforcing layer; a first cavity penetrating at least a portion of the first insulating layer; a second cavity penetrating at least a portion of the second insulating layer; a first electronic component disposed within the first cavity; and a second electronic component disposed within the second cavity. The reinforcing layer has a higher degree of stiffness than that of the first insulating layer, and the first insulating layer and the second insulating layer have substantially different thicknesses.

According to another aspect of the present disclosure, provided is a printed circuit board, the printed circuit board including: a reinforcing layer including a metal material; a first insulating layer disposed on an upper surface of the reinforcing layer; a second insulating layer disposed on a lower surface of the reinforcing layer; a first cavity penetrating upper and lower surfaces of the first insulating layer, and having the upper surface of the reinforcing layer as a bottom surface; a second cavity penetrating upper and lower surfaces of the second insulating layer, and having the lower surface of the reinforcing layer as a bottom surface; a first electronic component disposed within the first cavity; and a second electronic component disposed within the second cavity.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system;

FIG. 2 is a perspective view schematically illustrating an example of an electronic device; and

FIG. 3 is a cross-sectional view schematically illustrating a printed circuit board according to an example.

### DETAILED DESCRIPTION

Hereinafter, embodiments of the present disclosure will be described as follows with reference to the attached drawings. The shapes and sizes of elements in the drawings may be exaggerated or reduced for clearer description.

### Electronic Device

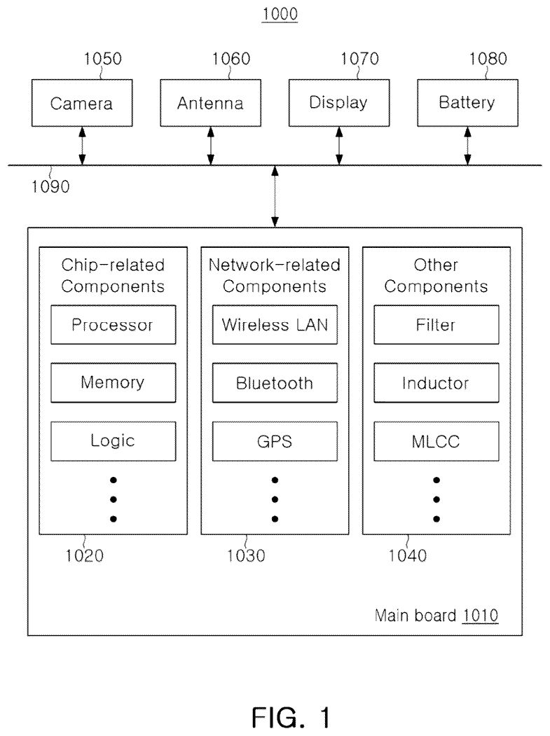

FIG. 1 is a block diagram illustrating an example embodiment of an electronic device system.

Referring to FIG. 1, an electronic device 1000 may accommodate a mainboard 1010 therein. The mainboard 1010 may include chip related components 1020, network related components 1030, other components 1040, and the like, physically or electrically connected thereto. These components may be connected to others to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip related components 1020 are not limited thereto, and may also include other types of chip related components. Also, the chip related components 1020 may be combined with each other.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+ (HSPA+), high speed downlink packet access+ (HSDPA+), high speed uplink packet access+ (HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, but may also include a variety of other wireless or wired standards or protocols. Also, the network related components 1030 may be combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, but may also include passive components used for various other purposes, or the like. Also, other components 1040 may be combined with each other, together with the chip related components 1020 or the network related components 1030 described above.

Depending on a type of the electronic device 1000, the electronic device 1000 may include other components that may or may not be physically or electrically connected to the mainboard 1010. The other components may include, for example, a camera module 1050, an antenna 1060, a display device 1070, and a battery 1080. However, the other components are not limited thereto, and may include an audio codec, a video codec, a power amplifier, a compass, an accelerometer, a gyroscope, a speaker, a mass storage unit (for example, a hard disk drive), a compact disk (CD) drive, a digital versatile disk (DVD) drive, or the like. The other components may also include other components used for various purposes depending on a type of electronic device 1000.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, but may be any other electronic device processing data.

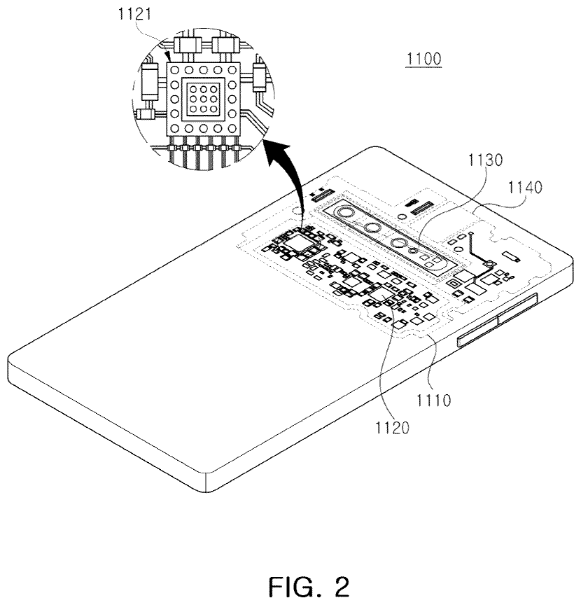

FIG. 2 is a perspective view illustrating an example embodiment of an electronic device.

Referring to FIG. 2, the electronic device may be, for example, a smartphone 1100. For example, a motherboard 1110 may be accommodated in the smartphone 1100, and various electronic components 1120 may be physically or electrically connected to the motherboard 1110. Also, other components which may or may not be physically or electrically connected to the motherboard 1110, such as a camera module 1130 and/or a speaker 1140, may be accommodated in the body 1101. A portion of the electronic components 1120 may be the chip related components, a component package 1121, for example, but are not limited thereto. The component package 1121 may be in the form of a printed circuit board on which electronic components including active components and/or passive components are surface-mounted. Alternatively, the component package 1121 may be in the form of a printed circuit board in which active components and/or passive components are embedded. The electronic device is not necessarily limited to the smartphone 1100, but may be other electronic devices as described above.

### Printed Circuit Board

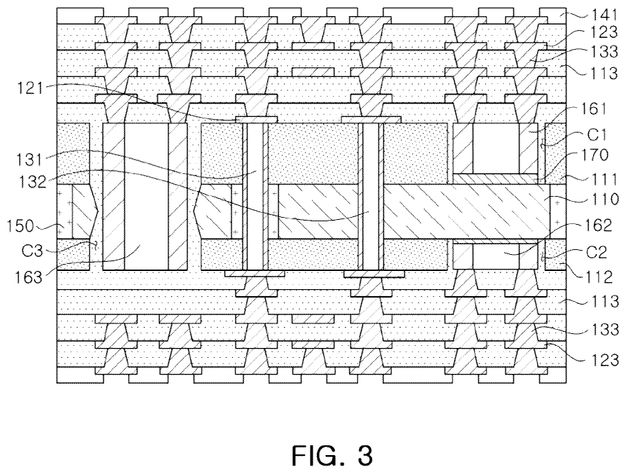

FIG. 3 is a cross-sectional view schematically illustrating a printed circuit board according to an example embodiment.

Referring to FIG. 3, the printed circuit board an example embodiment includes a reinforcing layer 110, a first insulating layer 111 disposed above the reinforcing layer second insulating layer 112 disposed below the 110, a reinforcing layer 110, a first cavity C1 penetrating at least a portion of the first insulating layer 111, a second cavity C2 penetrating at least a portion of the second insulating layer 112, a first electronic component 161 disposed within the first cavity C1, and a second electronic component 162 disposed within the second cavity C2. The reinforcing layer 110 may have a higher degree of stiffness than that of the first insulating layer 111, and the first insulating layer 111 and the second insulating layer 112 may have substantially different thicknesses.

A printed circuit board according to an example embodiment may further include a reinforcing layer 110 between the first insulating layer 111 and the second insulating layer 112 comprising a core of the board, thereby securing the stiffness of the printed circuit board and improving the bending characteristics of the printed circuit board. Stiffness is a property resisting deformation of shape or volume when subjected to external force. When the stiffness is high, the property to resist external force is strong, so deformation of shape or volume may be small. According to an example embodiment, a printed circuit board may have a reinforcing layer 110 having a higher degree of stiffness than that of the first insulating layer 111 and the second insulating layer 112, which may mean that a material included in the reinforcing layer 110 has a higher degree of stiffness than that of a material included in the first insulating layer 111 and the second insulating layer 112. That is, the reinforcing layer 110 may include a material having a higher degree of stiffness than that of the materials of the first insulating layer 111 and the second insulating layer 112. An embodiment thereof is not limited thereto, and the reinforcing layer 110 may have a higher degree of stiffness than that of a build-up insulating layer 113 to be described later. In addition, the reinforcing layer 110 may have a higher modulus of elasticity than that of the first insulating layer 111 and the second insulating layer 112. Since the modulus of elasticity may be defined as a ratio of stress and deformation, and may be used as a measure of the stiffness of a material, the fact that the reinforcing layer 110 has a higher degree of stiffness than the first insulating layer 111 and the second insulating layer 112 may mean that the material of reinforcing layer 110 has a higher modulus of elasticity than the materials of the first insulating layer 111 and the second insulating layer 112.

The modulus of elasticity of the reinforcing layer 110 and the first insulating layer 111 may be directly analyzed on a specimen of the reinforcing layer 110 and the first insulating layer 111, respectively, but an embodiment thereof is not limited thereto. A material used as the reinforcing layer 110 may be analyzed and an modulus of elasticity of the material may be used as a comparison target, and a material used as the first insulating layer 111 may be analyzed and an modulus of elasticity of the material may be used as a comparison target. As a non-limiting example, when the reinforcing layer 110 includes a metal material, the metal material may have a higher modulus of elasticity than that of an organic insulating material included in the first insulating layer 111 or the second insulating layer 112. The reinforcing layer 110 may include a material having a higher degree of stiffness than that of the first insulating layer 111 or the second insulating layer 112, and as a non-limiting example, the reinforcing layer 110 may include a metal material. That is, the printed circuit board according to the example may correspond to a so-called metal core board in which the reinforcing layer 110 includes a metal material, and the metal material include copper (Cu), aluminum (Al), silver (Ag), tin (Sn), gold (Au), nickel (Ni), lead (Pb), titanium (Ti), alloys thereof, or the like, and may also include an alloy such as stainless steel (SUS), Invar, or the like. When the reinforcing layer 110 includes a metal material, the reinforcing layer 110 may have a higher degree of stiffness than that of the first insulating layer 111 and the second insulating layer 112 including an organic insulating resin. Meanwhile, when the reinforcing layer 110 includes a metal material, the reinforcing layer 110 may be connected to a ground to improve grounding characteristics, and may also be used as a heat dissipation means. When the reinforcing layer 110 includes a metal material, it can have various effects, in addition to improving bending characteristics by securing stiffness.

Meanwhile, an embodiment thereof is not limited thereto, and the reinforcing layer 110 may include a glass material. In this case, the printed circuit board according to the example may be a glass core-type substrate in which the reinforcing layer 110 includes a glass plate, or the like. Glass may include pure silicon dioxide (about 100% SiO₂), soda-lime glass, borosilicate glass, alumino-silicate glass, or the like, but an embodiment thereof is not necessarily limited thereto. In addition, other additives may be included to form glass having specific physical properties. These additives may include calcium carbonate (e.g., lime) and sodium carbonate (e.g., soda), as well as magnesium, calcium, manganese, aluminum, lead, boron, iron, chromium, potassium, sulfur and antimony, and carbonates and/or oxides of these elements and other elements. In this case, the reinforcing layer 110 is a layer which is distinct from materials including glass fibers (glass cloth, and/or glass fabric), such as copper clad laminate, prepreg (PPG), or the like, and may be understood as, for example, plate glass, or the like. Even when the reinforcing layer 110 is a glass core such as plate glass, or the like containing glass, the reinforcing layer 110 may have a higher degree of stiffness than that of the first insulating layer 111 and the second insulating layer 112 including an organic insulating resin.

Since a printed circuit board according to an example includes a reinforcing layer 110 having a high degree of stiffness as a core layer, the first insulating layer 111 and the second insulating layer 112 may have substantially different thicknesses. The fact that the thicknesses of the first insulating layer 111 and the second insulating layer 112 are substantially different may mean that the thickness of the first insulating layer 111 may be thicker than the thickness of the second insulating layer 112, and conversely, may mean that the thickness of the second insulating layer 112 may be thicker than the thickness of the first insulating layer 111. In FIG. 3, it is illustrated that the thickness of the first insulating layer 111 disposed above the reinforcing layer 110 is thicker than the thickness of the second insulating layer 112, but an embodiment thereof is not necessarily limited thereto, and the thickness of the second insulating layer 112 may be thicker than the thickness of the first insulating layer 111. Since a printed circuit board according to an example includes a reinforcing layer 110 having high stiffness, even if the thicknesses of the first insulating layer 111 and the second insulating layer 112 are substantially different, warpage may be prevented during the manufacture and use of the printed circuit board, and different types of electronic components may be embedded within the first insulating layer 111 and the second insulating layer 112. The thicknesses of the first insulating layer 111 and the second insulating layer 112 may be measured by imaging a cross-section of the printed circuit board cut in a stacking direction using a scanning microscope, or the like, and may be measured as a distance across upper and lower surfaces of the first insulating layer 111 and a distance across upper and lower surfaces of the second insulating layer 112. The thicknesses of the first insulating layer 111 and the second insulating layer 112 may be an average value of the thicknesses of the first insulating layer 111 and the second insulating layer 112 measured at five arbitrary points, and may not include differences due to errors in the measurement processes or manufacturing operations. Since the thicknesses of the first insulating layer 111 and the second insulating layer 112 may be different from each other, a depth of the first cavity C1 formed in the first insulating layer 111 and a depth of the second cavity C2 formed in the second insulating layer 112 may be different from each other.

The first insulating layer 111 and the second insulating layer 112 may include an organic insulating material, respectively. The insulating material may include a thermosetting resin such as an epoxy resin, a thermoplastic resin such as polyimide, or a material including an inorganic filler, an organic filler, and/or glass fiber (glass cloth, and/or glass fabric) together with these resins. For example, as a material of the first insulating layer 111 and the second insulating layer 112, an insulating material such as Prepreg (PPG), Copper Clad Laminate (CCL), or the like, may be used. The first insulating layer 111 and the second insulating layer 112 may include the same insulating material, but an embodiment thereof is not necessarily limited thereto and the first insulating layer 111 and the second insulating layer 112 may include different insulating materials. As described above, since the first insulating layer 111 and the second insulating layer 112 may include an organic insulating material, the reinforcing layer 110 including a metal or glass plate may have a higher degree of stiffness than that of the first insulating layer 111 and the second insulating layer 112.

A printed circuit board according to an example may include a first cavity C1 penetrating at least a portion of the first insulating layer 111, and a second cavity C2 penetrating at least a portion of the second insulating layer 112. The first cavity C1 may be a so-called through-cavity penetrating upper and lower surfaces of the first insulating layer 111, and the first cavity C1 may have an upper surface of the reinforcing layer 110 as a bottom surface of the cavity. The second cavity C2 may be a so-called through-cavity penetrating upper and lower surfaces of the second insulating layer 112, and the second cavity C2 may have a lower surface of the reinforcing layer 110 as a bottom surface of the cavity. The first cavity C1 may be formed by stacking the first insulating layer 111 on the reinforcing layer 110, and then processing the same using the reinforcing layer 110 as a stopper of the cavity. In addition, from the same viewpoint, the second cavity C2 may be formed by stacking the second insulating layer 112 on the reinforcing layer 110, and then processing the same using the reinforcing layer 110 as a stopper of the cavity. Since the reinforcing layer 110 may have a material having a higher degree of stiffness than that of the first insulating layer 111 and the second insulating layer 112, it may be easy to form the first cavity C1 and the second cavity C2, respectively on a printed circuit board according to an example, even without including a separate stopper layer. Meanwhile, unlike a printed circuit board having a metal core as a heat dissipation means, since a printed circuit board according to an example may secure stiffness through a reinforcing layer 110 to improve bending characteristics, the reinforcing layer 110 may form the bottom surfaces of the first cavity C1 and the second cavity C2. When electronic components are disposed on a metal core, which is a heat dissipation means, there may be a problem in which heat is concentrated in an adhesive means connecting the electronic components, and there may also be a problem in which heat may be concentrated in the electronic components. However, since the printed circuit board according to the example includes the reinforcing layer 110 having high stiffness than the first insulating layer 111 and the second insulating layer 112, the bottom surfaces of the first cavity C1 and the second cavity C2 may be formed of a reinforcing layer 110.

Meanwhile, in FIG. 3, it is illustrated that an inner wall of each of the first cavity C1 and the second cavity C2 is substantially perpendicular to the bottom surfaces of each of the first cavity C1 and the second cavity C2, but an embodiment thereof is not necessarily limited thereto, and the first cavity C1 and the second cavity C2 may have a tapered shape so that a width on a side of the bottom surfaces thereof is narrower than a width on a side on an opposite side thereof.

As the thicknesses of the first insulating layer 111 and the second insulating layer 112 may be substantially different, the depths of the first cavity C1 and the second cavity C2 may be substantially different. The fact that the depths of the first cavity C1 and the second cavity C2 are substantially different may mean that the depth of the first cavity C1 may be deeper than the depth of the second cavity C2, and conversely, the fact that the depths of the first cavity C1 and the second cavity C2 are substantially different may mean that the depth of the second cavity C2 may be deeper than the depth of the first cavity C1. The depths of the first cavity C1 and the second cavity C2 may be measured by imaging a cross-section of the printed circuit board cut in a staking direction using a scanning microscope, or the like, and may be measured as a distance across an upper surface of the first insulating layer 111 and a bottom surface of the first cavity C1 and a distance across a bottom surface of the second insulating layer 112 and a bottom surface of the second cavity C2. The depth of the first cavity C1 and the depth of the second cavity C2 may be measured as an average value of each of the depths of the first cavity C1 and the second cavity C2 measured at five arbitrary points.

A printed circuit board according to an example may include a first electronic component 161 disposed in the first cavity C1 and a second electronic component 162 disposed in the second cavity C2. The first electronic component 161 and the second electronic component 162 may respectively be various types of electronic components, and may be an active component and/or a passive component. When the first electronic component 161 and the second electronic components 162 are active components, they may be various types of integrated circuit (IC) dies in which hundreds to millions thereof are integrated into a single chip. A passive component may be a chip-type capacitor such as a Multi-Layer Ceramic Capacitor (MLCC), such as a silicon capacitor, or the like, or a chip-type inductor such a power inductor (PI). However, an embodiment thereof is not limited thereto, and other types of active components and/or passive components may be disposed. Meanwhile, an embodiment thereof is not limited thereto, and the first electronic component 161 and the second electronic component 162 may be used without limitations as long as the first electronic component 161 and the second electronic component 162 are components or elements that can be mounted on a printed circuit board and connected to other semiconductor chips or electronic components to perform a function. The first electronic component 161 and the second electronic component 162 may respectively be connected to different semiconductor chips or may be connected to one semiconductor chip to transmit and receive power or signals.

In this case, the first electronic component 161 and the second electronic component 162 may include different electronic components, and first electronic component 161 and the second electronic component 162 may have substantially different thicknesses. As a printed circuit board according to an example may include a material having a high degree of stiffness in a reinforcing layer 110, the first insulating layer 111 and the second insulating layer 112 may have different thicknesses. Since the first cavity C1 and the second cavity C2 may have different depths, the first electronic component 161 mounted in the first cavity C1 and the second electronic component mounted in the second cavity C2 may have different thicknesses. That is, since a printed circuit board according to an example has a reinforcing layer 110 including a material having a high degree of stiffness in the central portion, it is possible to easily control the bending characteristics while mounting different kinds of components.

A printed circuit board according to an example may further include an adhesive layer 170 interposed between the first electronic component 161 and the reinforcing layer 110 and interposed between the second electronic component 162 and the reinforcing layer 110. A known adhesive means may be used as the adhesive layer 170, and the first electronic component 161 and the second electronic component 162 may be attached to the bottom surfaces of the first cavity C1 and the second cavity C2, respectively, through the adhesive layer 170. As the adhesive layer 170, a conventional adhesive film such as a die attach film (DAF) may be used, but an embodiment is not limited thereto, and any means that can attach other components such as electronic components or semiconductor chips to a printed circuit board, such as a known tape, may be used without limitations.

Meanwhile, a printed circuit board according to an example may further include a third cavity C3 penetrating the reinforcing layer 110, the first insulating layer 111, and the second insulating layer 112, and may further include a third electronic component 163 disposed within the third cavity C3.

In this case, a reinforcing layer 110 forming an inner wall of the third cavity C3 may have widths above and below the reinforcing layer 110 wider than a width in the central portion of the reinforcing layer 110. This may be the result of forming a structure in which a first insulating layer 111 and a second insulating layer 112 are stacked on upper and lower surfaces of the reinforcing layer 110, at least a portion of the first insulating layer 111 and the second insulating layer 112 are removed to expose portions of the upper and lower surfaces of the reinforcing layer 110, and then the exposed portions of the upper and lower surfaces of the reinforcing layer 110 are removed. In this case, when an etching process is performed in the operation of removing portions of the reinforcing layer 110 after removing the first insulating layer 111 and the second insulating layer 112, the widths of the third cavity C3 at the upper and lower surfaces of the reinforcing layer 110 may be formed to be wider than the width in the central portion of the third cavity C3 in the reinforcing layer 110.

Meanwhile, since the third cavity C3 may penetrate the reinforcing layer 110, the first insulating layer 111, and the second insulating layer 112, a depth of the third cavity C3 may be deeper than the depths of the first cavity C1 and the second cavity C2, and the depth of the third cavity C3 may be greater than the sum of the depths of the first cavity C1 and the second cavity C2.

The third electronic component 163 may be selected from one or more types of electronic components, and may be an active component and/or a passive component. In the case of an active component, the third electronic component 163 may be various kinds of integrated circuit (IC) dies in which hundreds to millions or more thereof are integrated in one chip. A passive component may be a chip-type capacitor such as a Multi-Layer Ceramic Capacitor (MLCC), such as a silicon capacitor, or the like, or a chip-type inductor such a power inductor (PI). However, an embodiment thereof is not limited thereto, and other types of active components and/or passive components may be disposed. Meanwhile, an embodiment thereof is not limited thereto, and the third electronic component 163 may be used without limitations as long as the third electronic component 163 is a component or element that can be mounted on a printed circuit board and connected to other semiconductor chips or electronic components to perform a function. The first electronic component 161 and the second electronic component 162 may respectively be connected to different semiconductor chips or may be connected to one semiconductor chip to transmit and receive power or signals.

In this case, the third electronic component 163 may include an electronic component, different from the first electronic component 161 and the second electronic component 162, and a thickness of the third electronic component 163 may be thicker than the thicknesses of the first electronic component 161 and the second electronic component 162. In addition, as a non-limiting example, the thickness of the third electronic component 163 may be greater than the sum of the thickness of the first electronic component 161 and the thickness of the second electronic component 162. That is, since a printed circuit board according to an example may include a reinforcing layer 110 having a high degree of stiffness, different kinds of electronic components may be mounted thereon.

Meanwhile, a lower surface of the third electronic component 163 may be substantially coplanar with the lower surface of the second insulating layer 112. This may be the result of using a temporary adhesive layer on the lower surface of the second insulating layer 112 in the operation of mounting the third electronic component 163 in the third cavity C3. That is, as the third cavity C3 has a through cavity structure, the third electronic component 163 is fixed to the lower surface of the second insulating layer 112 with a temporary adhesive layer, and then the third electronic component 163 is fixed thereto with a build-up insulating layer 113 to be described later, so that the lower surface of the third electronic component 163 may be substantially coplanar with the lower surface of the second insulating layer 112. In this case, the fact that any two surfaces are substantially coplanar may mean that the two surfaces form a so-called coplanar surface, in which the two surfaces are disposed on the same surface. Meanwhile, an embodiment thereof is not limited thereto, and although not shown in FIG. 3, when the third electronic component 163 is fixed in a direction of the upper surface of the first insulating layer 111, the upper surface of the third electronic component 163 may be substantially coplanar with the upper surface of the first insulating layer 111. In this case, a build-up via layer 133 to be described later penetrates the second insulating layer 112, so that the third electronic component 163 may be connected to a lower side thereof.

A printed circuit board according to an example may further include a filler 150 disposed on a side surface of the reinforcing layer 110. The filler 150 may include an insulating material, and the filler 150 may include an organic insulating material different from that of the first insulating layer 111 and the second insulating layer 112. For example, the filler 150 and the first insulating layer 111 and the second insulating layer 112 may be layers which are physically or materially distinct from each other. This may be a material for fixing the reinforcing layer 110 to an inside of a jig, so it may include underfill or epoxy molding compound (EMC), but an embodiment thereof is not limited thereof, and any resin that can be used in the field of a printed circuit board may be used without limitations.

When the reinforcing layer 110 includes a metal material, a filler 150 including an insulating material may cover a side surface of the reinforcing layer 110, to prevent the side surface of the reinforcing layer 110 from being exposed to the side surface of the printed circuit board and connected to the outside. Meanwhile, when the reinforcing layer 110 includes a glass material, since the filler 150 is disposed on a side surface of the reinforcing layer 110, cracks or breakage that may occur as the side surface of the reinforcing layer 110 is exposed to the side surface of the printed circuit board may be prevented.

Since the first insulating layer 111 and the second insulating layer 112 may be stacked after the filler 150 is formed on the side surface of the reinforcing layer 110, the thickness of the reinforcing layer 110 and the thickness of the filler 150 may be substantially the same, and the upper and lower surfaces of the reinforcing layer 110 and the upper and lower surfaces of the filler 150 may be substantially coplanar with each other. A dispositional relationship between the first through-via 131, the filler 150, and the reinforcing layer 110 will be described later.

A printed circuit board according to an example may further include pads 121 respectively disposed on the first insulating layer 111 and the second insulating layer 112, and may further include a first through-via penetrating the first insulating layer 111, the second insulating layer 112, and the reinforcing layer 110 to connect the pads 121 to each other and spaced apart from the reinforcing layer 110, and a second through-via 132 penetrating the first insulating layer 111, the second insulating layer 112, and the reinforcing layer 110 to connect the pads 121 to each other and in contact with the reinforcing layer 110.

The pad 121 may be formed on the upper surface of the first insulating layer 111 and the lower surface of the second insulating layer (112), respectively, and the pad 121 may include a metal material. As the metal material, copper (Cu), aluminum (Al), silver (Ag), tin (Sn), gold (Au), nickel (Ni), lead (Pb), titanium (Ti), or alloys thereof may be used. The metal material may preferably include copper (Cu), but an embodiment thereof is not limited thereto. Each pad 121 may perform various functions depending on the design thereof. For example, the pad may include a signal pad, a power pad, a ground pad, and the like, and an embodiment thereof is not limited thereto, and may also function as a pad for mounting electronic components, chips, and the like.

The first through-via 131 and the second through-via 132 may include a metal material, respectively. The metal material may include copper (Cu), aluminum (Al), silver (Ag), tin (Sn), gold (Au), nickel (Ni), lead (Pb), titanium (Ti), and/or alloys thereof. The metal material may preferably include copper (Cu), but an embodiment thereof is not limited thereto. The first through-via 131 and the second through-via 132 may penetrate the first insulating layer 111, the reinforcing layer 110, and the second insulating layer 112, respectively, to connect the pads 121 to each other. Each of the first through-via 131 and the second through-via 132 may perform various functions depending on a design thereof. For example, the via may include ground vias, power vias, signal vias, and the like. The first through-via 131 and the second through-via 132 may have a through-via structure other than a microvia, and each of the first through-via 131 and the second through-via 132 may include a conformal via formed along a through-hole, but an embodiment thereof is not limited thereto and may also include a filled via filling the through-hole. In FIG. 3, it is illustrated that the first through-via 131 and the second through-via 132 include a conformal via, respectively, and in this case, it is illustrated that a metal material may be formed along an inner wall of the through-hole to be electrically connected thereto, and a plug may be filled in a central portion of the through-hole, but an embodiment thereof is not necessarily limited thereto, and as described above, the first through-via 131 and the second through-via 132 may have the form of a filled via. The first through-via 131 and the second through-via 132 may have an approximately circular or elliptical shape on a plane, but the present disclosure is not limited thereto. For example, in terms of securing close contact through an increase in a specific surface area, the first through-via 131 and the second through-via 132 may have a polygonal shape on a plane, and may also have a so-called flower shape in which a number of circles or ellipses are overlapped.

The first through-via 131 may be spaced apart from a reinforcing layer 110, and a filler 150 may be disposed between the first through-via 131 and the reinforcing layer 110. When the reinforcing layer 110 includes a metal material, the first through-via 131 and the reinforcing layer 110 may be spaced apart from each other so that the first through-via 131 and the reinforcing layer 110 are not connected to each other and have an open circuit design. In this case, the first through-via 131 may perform the function of a power via or a signal via. The second through-via 132 may be in contact with the reinforcing layer 110. When the reinforcing layer 110 includes a metal material, the reinforcing layer 110 may function as a metal layer for grounding, and the second through-via 132 may function as a ground via, and in some cases, may also function as a heat dissipation via for heat dissipation characteristics.

A structure in which the first through-via 131 is spaced apart from the reinforcing layer 110 may be formed through the following manufacturing operations. First, a through-hole for the first through-via 131 may be formed in the reinforcing layer 110, and then the through-hole may be filled with a filler 150. Thereafter, a first insulating layer 111 and a second insulating layer 112 may be formed on the reinforcing layer 110, respectively, and a through-hole penetrating the first insulating layer 111, the second insulating layer 112, and the filler 150, thereby forming a through-hole for the first through-via 131. Thereby, the through-hole may be spaced apart from the reinforcing layer 110, and a first through-via 131 may be formed in the through-hole and the first through-via 131 may have a structure spaced apart from the reinforcing layer 110.

A structure in which the second through-via 132 is in contact with the reinforcing layer 110 may be formed through the following manufacturing operations. After forming a first insulating layer 111 and a second insulating layer 112 on the reinforcing layer 110, a through-hole penetrating the first insulating layer 111, the reinforcing layer 110, and the second insulating layer 112 may be formed. Thereafter, a second through-via 131 may be formed in the through-hole and the first through-via 131 may have a structure in contact with the reinforcing layer 110.

Meanwhile, in FIG. 3, it is illustrated that a pad 121 is formed on the first insulating layer 111 and the second insulating layer 112, respectively, but the present disclosure is not necessarily limited thereto, and wiring patterns may be formed on the same layer, in addition to pads.

A printed circuit board according to an example may further include a build-up insulating layer 113 disposed on the first insulating layer 111 and the second insulating layer 112, a build-up wiring layer 123 disposed on the build-up insulating layer 113, and a build-up via layer 133 penetrating at least a portion of the build-up insulating layer 113 to connect the build-up wiring layer 123 to each other, or to connect the first electronic component 161, the second electronic component 162, or the third electronic component 163, to each other.

The build-up insulating layer 113 may include one or more insulating layers, and may include an organic insulating material. The organic insulating material may include a thermosetting resin such as epoxy resin, a thermoplastic resin such as polyimide, or a material including an inorganic filler, an organic filler and/or glass fibers (glass cloth, and/or glass fabric) together with the above-described resins. For example, the insulating material may preferably, include Ajinomoto build-up film (ABF), but the present disclosure is not limited thereto, and other polymeric materials may be used as the insulating material. As a non-limiting example, the insulating material may be a non-photosensitive insulating material such as prepreg (PPG), or the like, or may be a photosensitive insulating material such as Photo Imageable Dielectric (PID), or the like, or the insulating material may include an adhesive sheet such as a bonding sheet (BS), or the like.

In this case, the build-up insulating layer may fill the first cavity C1 and embed the first electronic component 161, fill the second cavity C2 and embed the second electronic component 162, and fill the third cavity C3 and embed the third electronic component 163.

The build-up wiring layer 123 may include one or more wiring layers, and may include a metal. The metal may include copper (Cu), aluminum (Al), silver (Ag), tin (Sn), gold (Au), nickel (Ni), lead (Pb), titanium (Ti), or alloys thereof. Preferably, the metal may include copper (Cu), but the present disclosure is not limited thereto.

Each of the build-up wiring layers 123 may perform various functions depending on a design thereof. For example, the build-up wiring layers 123 may include a signal pattern, a power pattern, a ground pattern, and the like. Each of the patterns may have various forms such as a line, a plane, and a pad. Each of the build-up wiring layers 123 may include an electroless plating layer (or chemical copper) and an electrolytic plating layer (or electrolytic copper). Alternatively, each of the build-up wiring layers 123 may include a metal foil (or copper foil) and an electrolytic plating layer (or electrolytic copper). Alternatively, each of the build-up wiring layers 123 may include a metal foil (or copper foil), an electroless plating layer (or chemical copper), and an electrolytic plating layer (or electrolytic copper). A sputtering layer may be included instead of an electroless plating layer (or chemical copper), and both thereof may be included if necessary. The build-up via layer 133 may include a metal. The metal may include copper (Cu), aluminum (Al), silver (Ag), tin (Sn), gold (Au), nickel (Ni), lead (Pb), titanium (Ti), and/or alloys thereof. The metal may preferably include copper (Cu), but the present disclosure is not limited thereto. The build-up via layer 133 may include a filled via filling a via hole, respectively, but may also include a conformal via disposed along a wall surface of the via hole. The micro via may be disposed in a stacked type and/or a staggered type. The build-up via layer 133 may perform various functions depending on a design of thereof. For example, the build-up via layers may include ground vias, power vias, signal vias, and the like. The build-up via layer 133 may include an electroless plating layer (or chemical copper) and an electrolytic plating layer (or electrolytic copper), similar to the build-up wiring layer 123. Alternatively, it may include a metal foil (or copper foil) and an electrolytic plating layer (or electrolytic copper). Instead of the electroless plating layer (or chemical copper), a sputtering layer may be included, and if necessary, both thereof may be included. The first electronic component 161, the second electronic component 162, and the third electronic component 163 may respectively be connected to the build-up wiring layer 123 through the build-up via layer 133.

The build-up wiring layer 123 and the build-up via layer 133 may be formed by any one of a semi-additive process (SAP) or a modified additive process (MSAP), tenting (TT), or a subtractive method, but the present disclosure is no limited thereto, and any method that can form a circuit on a printed circuit board may be used without limitations. In addition, the build-up wiring layer 123 and the build-up via layer 133 may be formed using different methods depending on the purpose and design, respectively.

A printed circuit board according to an example may further include a solder resist layer 141 disposed on the build-up insulating layer 113. The solder resist layer 141 may be disposed on uppermost and lowermost sides of the printed circuit board to protect the printed circuit board from the surrounding environment. The solder resist layer 141 may use a known solder resist, and the solder resist layer 141 may include a liquid or film-type material, but the present disclosure is not limited thereto, and other types of insulating materials may be used, and the solder resist layer 141 may include a thermosetting resin and an inorganic filler dispersed in the thermosetting resin, but not include glass fibers. The insulating resin may be a photosensitive insulating resin, and the filler may be an inorganic filler and/or an organic filler, but the present disclosure is not limited thereto, and other polymer materials may be used as needed. The solder resist layer 141 may have an opening, and at least a portion of the build-up wiring layer 123 may be exposed through the opening. A portion of the build-up wiring layer 123 exposed through the opening may be connected to a device such as a semiconductor chip, or the like, and may also be connected to a main board or other printed circuit boards. That is, an wiring layer exposed through the opening functions as a pad, and a surface treatment layer may be further formed on the pad as needed. Alternatively, a metal bump or post may be further formed on the pad, or the pad may have a structure protruding in the form of a pillar as needed.

Meanwhile, a printed circuit board according to an example is not limited to the configuration illustrated in FIG. 3, and other configurations may be included or, in some cases, may be omitted. For example, the build-up insulating layer 113, the build-up wiring layer 123, and the build-up via layer 133 may have a so-called redistribution structure having a fine pitch structure in some layers depending on the design, and may have various structures depending on the design, such as a cavity formed in the build-up insulating layer 113 into which electronic components, connection structures, bridges, or the like, are embedded. That is, those skilled in the art in the relevant technical field can include or omit additional configurations that can be utilized.

Meanwhile, in FIG. 3, it is illustrated that thickness of the first insulating layer 111 disposed above the reinforcing layer 110 is greater than a thickness of the second insulating layer 112 disposed below the reinforcing layer 110, but as described above, an embodiment thereof is not necessarily limited thereto. That is, if the thicknesses of the first insulating layer 111 and the second insulating layer 112 can be substantially different, a size relationship and upper and lower dispositional relationship thereof are not limited to those illustrated in FIG. 3.

Meanwhile, in FIG. 3, it is illustrated that a connection direction of the third electronic component 163 is upward, but the present disclosure is not necessarily limited thereto, and as described above, the third electronic component 163 may be connected to a lower side thereof.

In the example embodiment, the meaning on a cross-section may mean a cross-sectional shape when an object is vertically cut, or a cross-sectional shape when the object is viewed from the side. Also, the meaning on a plane may refer to a planar shape when the object is horizontally cut, or a planar shape when the object is viewed from the top or the bottom.

In the example embodiments, the terms “an upper side, an upper portion, an upper surface, and the like, are used to refer to a direction toward a mounting surface on which an electronic component may be mounted based on the cross-section of the drawing for convenience, and the terms “a lower side, a lower portion, a lower surface, and the like, are used as the opposite directions. However, the direction is defined as above for ease of description, and the scope of the claims is not limited to any particular example by the descriptions of the directions.

In the example embodiments, the term “connected” may not only refer to “directly connected” but also include “indirectly connected” by may refer to of an adhesive layer, or the like. Also, the term “electrically connected” may include both of the case in which elements are “physically connected” and the case in which elements are “not physically connected.” Further, the terms “first,” “second,” and the like may be used to distinguish one element from the other, and may not limit a sequence and/or an importance, or others, in relation to the elements. In some cases, a first element may be referred to as a second element, and similarly, a second element may be referred to as a first element without departing from the scope of right of the example embodiments.

In the example embodiments, determination may be performed by including process errors, positional deviations, errors at the time of measurement, which may occur substantially in a manufacturing process. For example, being substantially vertical may include not only being completely vertical but also being approximately vertical. Furthermore, being substantially coplanar may include not only a case in which elements are completely on the same plane, but also a case in which the elements are approximately on the same plane. Further, being substantially different may be understood as the opposite concept of being substantially the same, and may mean that there can be structural differences, not differences due to errors that may occur during the manufacturing or measurement operations.

In the present disclosure, the same insulating material may denote not only the same insulating material but also the same type of insulating material. Accordingly, the compositions of the insulating materials may be substantially the same, but specific composition ratios thereof may be slightly different.

In the example embodiments, the term “example embodiment” may not refer to one same example embodiment, and may be provided to describe and emphasize different unique features of each example embodiment. The above suggested example embodiments may be implemented do not exclude the possibilities of combination with features of other example embodiments. For example, even though the features described in one example embodiment are not described in the other example embodiment, the description may be understood as being relevant to the other example embodiment unless otherwise indicated.

The terms used herein describe particular embodiments only, and the present disclosure is not limited thereby. As used herein, the singular forms “a,” “an,” and “the” are intended to include the plural forms as well, unless the context clearly indicates otherwise.

As set forth above, as one of the effects of the present disclosure, a printed circuit board for controlling warpage on a multilayer substrate while implementing a cavity for mounting an electronic component, or the like, may be provided.

As another effect of the effects of the present disclosure, a printed circuit board for mounting various types of electronic components may be provided.

As another effect of the effects of the present disclosure, a printed circuit board for improving reliability may be provided.

While the example embodiments have been illustrated and described above, it will be apparent to a person skilled in the art that modifications and variations could be made without departing from the scope of the present disclosure as defined by the appended claims.

What is claimed is:

1. A printed circuit board, comprising:
a reinforcing layer;
a first insulating layer disposed above the reinforcing layer;
a second insulating layer disposed below the reinforcing layer;
a first cavity penetrating at least a portion of the first insulating layer;
a second cavity penetrating at least a portion of the second insulating layer;
a first electronic component disposed within the first cavity; and
a second electronic component disposed within the second cavity,
wherein the reinforcing layer has a higher degree of stiffness than that of the first insulating layer, and
the first insulating layer and the second insulating layer have substantially different thicknesses.

2. The printed circuit board of claim 1, wherein a depth of the first cavity and a depth of the second cavity are substantially different.

3. The printed circuit board of claim 1, wherein the thickness of the first insulating layer is thicker than the thickness of the second insulating layer.

4. The printed circuit board of claim 1, further comprising:
a third cavity penetrating the reinforcing layer, the first insulating layer, and the second insulating layer; and
a third electronic component disposed within the third cavity.

5. The printed circuit board of claim 4, wherein a depth of the third cavity is deeper than the depth of the first cavity and the depth of the second cavity.

6. The printed circuit board of claim 4, wherein a width of the third cavity above the reinforcing layer is wider than a width in a central portion of the third cavity in the reinforcing layer.

7. The printed circuit board of claim 4, wherein a thickness of the third electronic component is thicker than a thickness of the first electronic component and a thickness of the second electronic component.

8. The printed circuit board of claim 1, further comprising:
a filler disposed on a side surface of the reinforcing layer.

9. The printed circuit board of claim 1, further comprising:
a build-up insulating layer respectively disposed on the first insulating layer and the second insulating layer; and
a build-up wiring layer disposed on the build-up insulating layer,
wherein the build-up insulating layer disposed in the first cavity and the second cavity.

10. The printed circuit board of claim 1, wherein the reinforcing layer includes a metal material.

11. The printed circuit board of claim 1, wherein the reinforcing layer includes a glass material.

12. A printed circuit board, comprising:
a reinforcing layer including a metal material;
a first insulating layer disposed on an upper surface of the reinforcing layer;
a second insulating layer disposed on a lower surface of the reinforcing layer;
a first cavity penetrating upper and lower surfaces of the first insulating layer, and having the upper surface of the reinforcing layer as a bottom surface;
a second cavity penetrating upper and lower surfaces of the second insulating layer, and having the lower surface of the reinforcing layer as a bottom surface;
a first electronic component disposed within the first cavity; and
a second electronic component disposed within the second cavity.

13. The printed circuit board of claim 12, further comprising:
a third cavity penetrating the first insulating layer, the second insulating layer, and the reinforcing layer; and
a third electronic component disposed within the third cavity.

14. The printed circuit board of claim 12, further comprising:
pads respectively disposed on the first insulating layer and the second insulating layer; and
a first through-via penetrating the first insulating layer, the second insulating layer, and the reinforcing layer, to connect first pads of the pads to each other, and spaced apart from the reinforcing layer; and
a second through-via penetrating the first insulating layer, the second insulating layer, and the reinforcing layer, to connect second pads of the pads to each other, and in contact with the reinforcing layer.

15. The printed circuit board of claim 12, further comprising:
pads respectively disposed on the first insulating layer and the second insulating layer; and
a through-via penetrating the first insulating layer, the second insulating layer, and the reinforcing layer, to connect the pads to each other, and spaced apart from the reinforcing layer.

16. The printed circuit board of claim 15, further comprising:
a filler interposed between the through-via and the reinforcing layer, and covering a side surface of the reinforcing layer.

17. The printed circuit board of claim 12, further comprising:
pads respectively disposed on the first insulating layer and the second insulating layer; and
a through-via penetrating the first insulating layer, the second insulating layer, and the reinforcing layer, to connect the pads to each other, and in contact with the reinforcing layer.

18. The printed circuit board of claim 12, further comprising:
a build-up insulating layer respectively disposed on the first insulating layer and the second insulating layer; and
a build-up wiring layer disposed on the build-up insulating layer,
wherein the build-up insulating layer disposed in the first cavity and the second cavity.

19. The printed circuit board of claim 12, further comprising:
an adhesive layer interposed between the reinforcing layer and the first electronic component.
